(19) United States
(12) Patent Application Publication
(10) Pub. No.: US 2017/0202099 A1
(43) Pub. Date: Jul. 13, 2017

(54) LATCH ASSEMBLY INCLUDING A COVER HAVING A CAVITY AND A LEVER DISPOSED IN THE CAVITY

(71) Applicant: HEWLETT PACKARD ENTERPRISE DEVELOPMENT LP, Houston, TX (US)

(72) Inventors: Minh H NGUYEN, Katy, TX (US); Keith A SAUER, Spring, TX (US); Kelly K SMITH, Spring, TX (US)

(73) Assignee: HEWLETT PACKARD ENTERPRISE DEVELOPMENT LP, Houston, TX (US)

(21) Appl. No.: 15/316,776

(22) PCT Filed: Jul. 29, 2014
(86) PCT No.: PCT/US2014/048546

§ 371 Date: Dec. 6, 2016

(51) Int. Cl. H05K 5/02; H05K 5/03; E05B 5/00; E05C 19/10; E05B 65/02; E05B 13/10

(52) U.S. Cl. CPC H05K 5/0221; E05B 65/02; E05B 13/10; E05B 5/00; E05C 19/10; H05K 5/023; H05K 5/03

(57) ABSTRACT

A latch assembly includes a lever and a cover. The lever includes a main portion, a cam portion, and an end portion. The cam portion includes a first cam surface and a second cam surface. The lever rotates between an install hood position and an uninstall hood position. The cover couples the lever and the hood. The cover includes a cavity to receive the lever.

### BACKGROUND

Latch assemblies include movable components to latch and unlatch respective objects. In a latched state, the latch assemblies secure the latched objects to prevent inadvertent movement and separation of the respective objects from each other. In an unlatched state, the latch assemblies enable the objects to be moved and separated from each other.

### BRIEF DESCRIPTION OF THE DRAWINGS

Non-limiting examples are described in the following description, read with reference to the figures attached hereto and do not limit the scope of the claims. Dimensions of components and features illustrated in the figures are chosen primarily for convenience and clarity of presentation and are not necessarily to scale. Referring to the attached figures:

FIG. 1 is a block diagram illustrating a latch assembly according to an example.

FIG. 2 is a top view illustrating a latch assembly according to an example.

FIG. 3 is a schematic view illustrating the latch assembly of FIG. 2 in an unassembled state according to an example.

FIG. 4 is a perspective view illustrating the latch assembly of FIG. 2 in an uninstall hood position according to an example.

FIG. 5 is a perspective view illustrating the latch assembly of FIG. 2 in an install hood position according to an example.

FIG. 6 is a perspective view illustrating the latch assembly of FIG. 2 in an install hood position and latch position according to an example.

FIG. 7 is a perspective view illustrating the latch assembly of FIG. 2 in an install hood position and unlatch position according to an example.

FIG. 8 is a block view illustrating a latch assembly according to an example.

FIG. 9 is a schematic view illustrating a server y e according to an example.

FIG. 10 is a flowchart illustrating a latching method of a latch assembly according to an example.

### DETAILED DESCRIPTION

Latch assemblies include movable components such as levers or push buttons to latch and unlatch respective objects. In a latched state, the latch assemblies attempt to secure the latched objects to prevent inadvertent movement and separation of the latched objects from each other. In an unlatched state, the latch assemblies enable the objects to be moved and separated from each other. However, applications of latch assemblies including push buttons may be limited. Further, other types of latch assemblies having a relatively, thick profile due to an arrangement of their components may also be limited. However, relatively, thick-profile latch assemblies may take up too much room, for example, in relatively, thin-profile latch assembly applications.

In examples, a latch assembly includes a lever and a cover. The ever includes a main portion, a cam portion, and an end portion. The cam portion includes a first cam surface and a second cam surface. The lever rotates between an install hood position and an uninstall hood position. For example, a server system such as a rack server may include a chassis having respective interior compartments to store electronic components including dual, inline, memory modules (DlMMs), and hoods to removably cover the respective interior compartments.

The latch assembly may movably latch and unlatch a respective hood onto the chassis. That, is, the first cam surface may push against a first surface to slide a hood in a first direction to place the hood in the install hood position. Also, the second cam surface may push against a second surface to slide the hood in a second direction to place the hood in the uninstall hood position. The cover having a cavity couples the lever and the hood resulting in a relatively, thin profile latch assembly. Thus, the latch assembly may be adequately used in a variety of applications including relatively, thin-profile, latch assemblies applications such as movably latching and unlatching a respective hood onto a chassis of a server system.

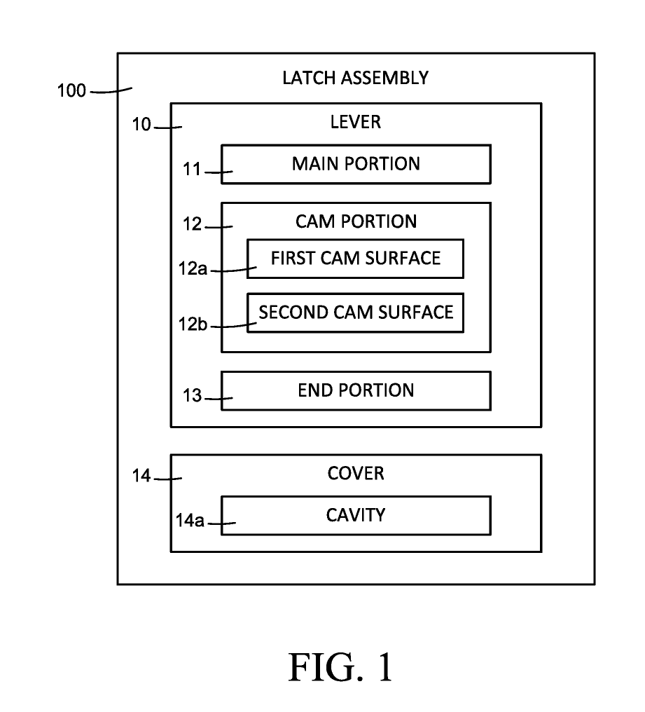

FIG. 1 is a block diagram illustrating a latch assembly according to an example. In some examples, the latch assembly 100 includes a lever 10 and a cover 14. The lever 10 includes a main portion 11, a cam portion 12, and an end portion 13. The main portion 11 may be disposed between the cam portion 12 and the end portion 13. The cam portion 12 includes a first cam surface 12a and a second cam surface 12b. The lever 10 rotates between an install hood position and an uninstall hood position. In some examples, in the install hood position, a hood is directed onto a chassis of a server system. The hood, for example, may enclose an internal compartment in which components such as DlMMs reside. The first cam surface 12a may push against a first surface to slide a hood in a first direction to place the hood in the install hood position. The first surface, for example, may include a front wall of a retaining bracket of the chassis.

Referring to FIG. 1, in some examples, in the uninstall hood position, the hood is directed away from the chassis of the server system, The second cam surface 12b may push against a second surface to slide the hood in a second direction to place the hood in the uninstall hood position. The second surface, for example, may include a rear wall of the retaining bracket of the chassis. That is, a cam profile may act in cooperation with a respective surface of a server system to effect movement of the hood. For example, at a front end of the lever 10, a cam profile acts with a first surface of an internal bracket to allow the hood to move forward to install the hood onto the chassis by pushing the lever 10 down. Further, the cam profile acts with a second surface of the internal bracket to allow the hood to move backwards to uninstall the hood from the chassis by pulling the lever 10 up. The cover 14 couples to the lever 10 and the hood. The cover 14 includes a cavity 14a to receive the lever 10.

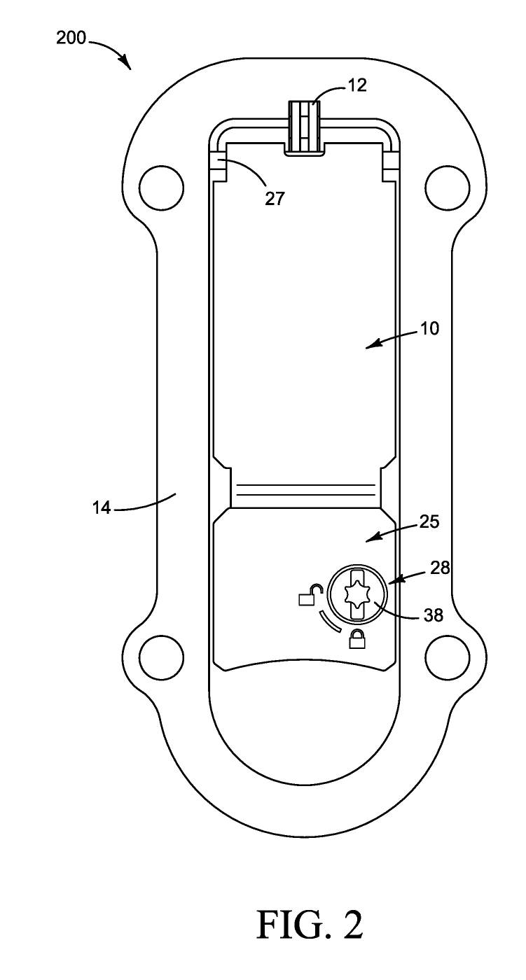

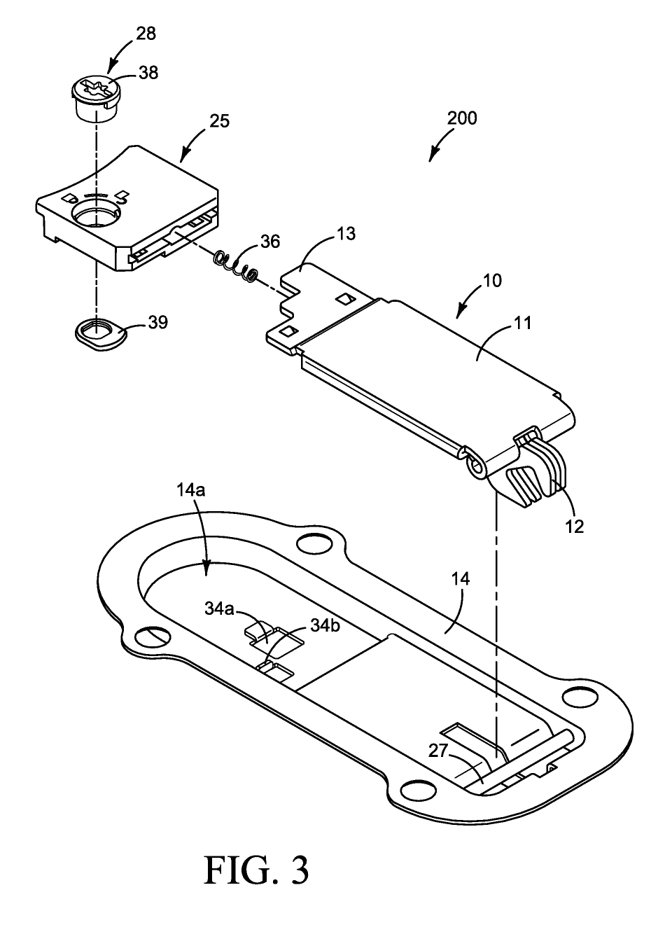

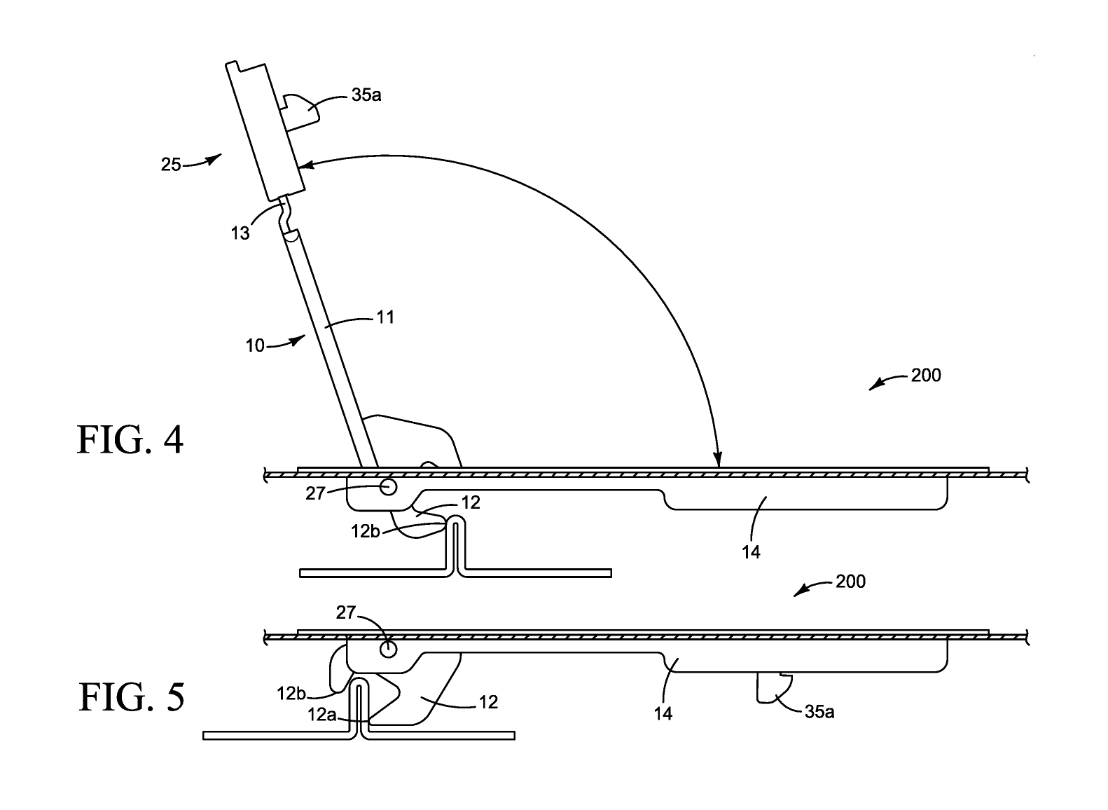

FIG. 2 is a top view illustrating a latch assembly according to an example. FIG. 3 is a schematic view illustrating the latch assembly of FIG. 2 in an unassembled state according to an example. In some examples, a latch assembly 200 may include a lever 10, a latch member 25, a resilient member 36, a lock device 28, a cover 14, and a fastener 27. The lever 10 may include a main portion 11, a cam portion 12, and an end portion 13. The main portion 11 may be disposed between the cam portion 12 and the end portion 13. The cam portion 12 includes a first cam surface 12a (FIG. 5) and a second cam surface 12b (FIG. 4). In some examples, the first and second cam surfaces 12a and 12b may be curved. The lever 10 may comprise metal. In some examples, the latch member 25 may include a hook portion 35a. The latch member 25 may comprise plastic. The lock device 28 may include a lock screw 38 and a lock tab 39. The cover 14 may include a cavity 14a, a latch recess 34a, and a stop member 34b. In some examples, the cover 14 may comprise metal. In some examples, the fastener 27 may include a pin, for example, to movably couple the lever 10 to the cover 14.

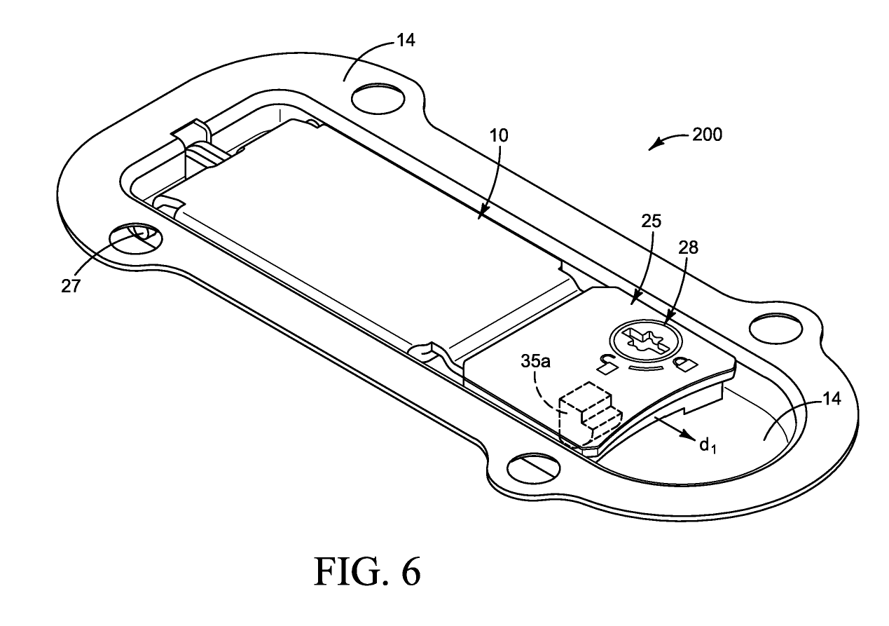

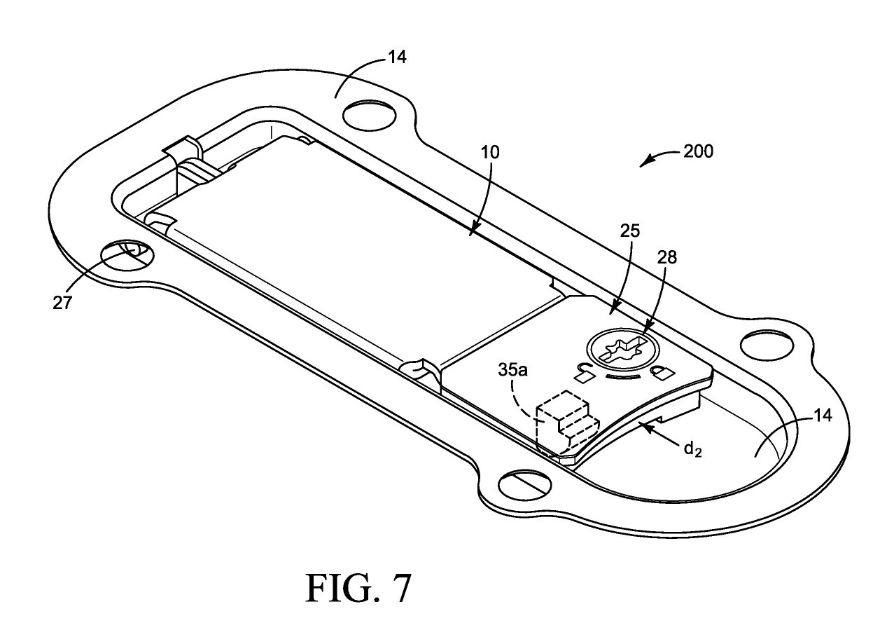

FIG. 4 is a perspective view illustrating the latch assembly of FIG. 2 in an uninstall hood position according to an example. FIG. 5 is a perspective view illustrating the latch assembly of FIG. 2 in an install hood position according to an example. FIG. 6 is a perspective view illustrating the latch assembly of FIG. 2 in an install hood position and a latch position according to an example. FIG. 7 is a perspective view illustrating the latch assembly of FIG. 2 in an install hood position and an unlatch position according to an example. Referring to FIGS. 4-7, in some examples, the fastener 27 may couple the lever 10 to the cover 14. The fastener 27 includes a longitudinal axis in which the lever 10 may rotate about it.

Referring to FIGS. 4-7, in some examples, the latch member 25 is coupled to the end portion 13 of the lever 10. The latch member 25 may be movable between a latch position to latch the lever 10 in the install hood position and an unlatch position to unlatch the lever 10. For example, the latch member 25 may move in a first direction d₁ away from the main portion 11 of the lever 10 to latch the lever 10 in the install hood position. Also, the latch member 25 may move in a second direction d₂ toward the main portion 11 to unlatch the lever 10 to enable the lever 10 to move to the uninstall hood position. Also, a cam profile may act with a respective surface of a server system to effect movement of the hood. For example, at a front end of the lever 10 close to a fastener 27, a cam profile acts with a wall from an internal bracket to allow the hood to move forward to install the hood onto the chassis by pushing the lever 10 down or move backwards to uninstall it from the chassis by pulling the lever 10 up.

Referring to FIGS. 4-7, in some examples, the latch member 25 includes a hook portion 35a. For example, the hook portion 35a may engage the cover 14 in the install hood position in response to when the latch member 25 is placed in the latch position. For example, the latch recess 34a may receive the hook portion 35a of the latch member 25 in the latch position. The resilient member 36 may be disposed between the lever 10 and the latch member 25 to provide a resilient force there between. For example, the resilient member 36 may include a spring to force the latch member 25 in the first direction d₁ away from the main portion 11 of the lever 10. In some examples, during movement of the lever 10 into the install position, the hook portion 35a may be biased into the lock position. In some examples, to place the latch member 25 in the unlatch position, a user may provide a manual force opposite to and greater than the resilient force. For example, the user may apply a force in the second direction d₂. Alternatively, movement of the lever 10 by a user may enable the hook portion 35a to clear the latch recess 34a to unlatch.

Referring to FIGS. 4-7, in some examples, the lock device 28 includes a lock screw 38 and a lock tab 39. The lock screw 38 may be disposed in the latch member 25. The lock tab 39 is attached to the lock screw 38. The lock screw 39 may move the lock tab 39 between a lock position and an unlock position. In the lock position, for example, the lock screw 38 may position the lock tab 39 to engage the cover 14 such as the stop member 34b to prevent the latch member 25 from advancing to the unlatch position. Thus, the latch member 25 may securely remain in the latch position during shocks and vibrations.

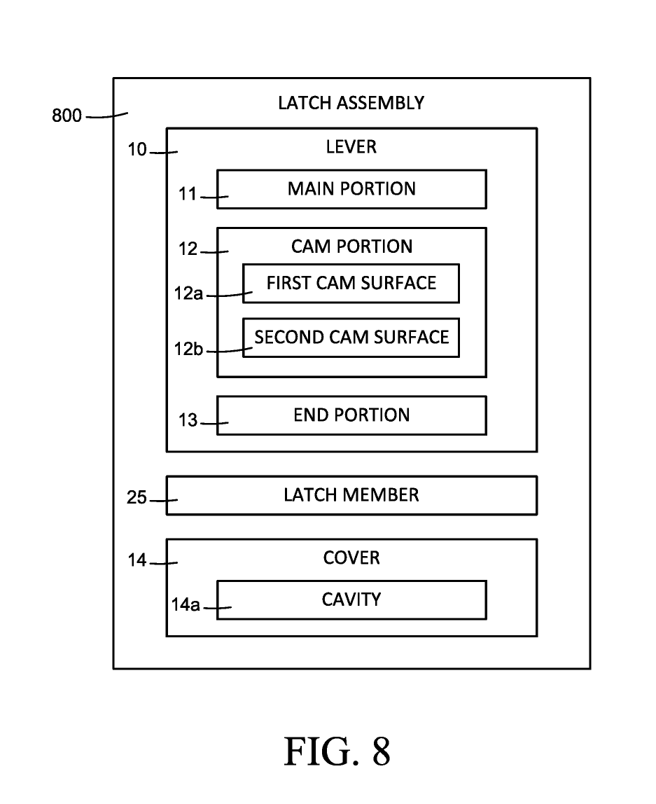

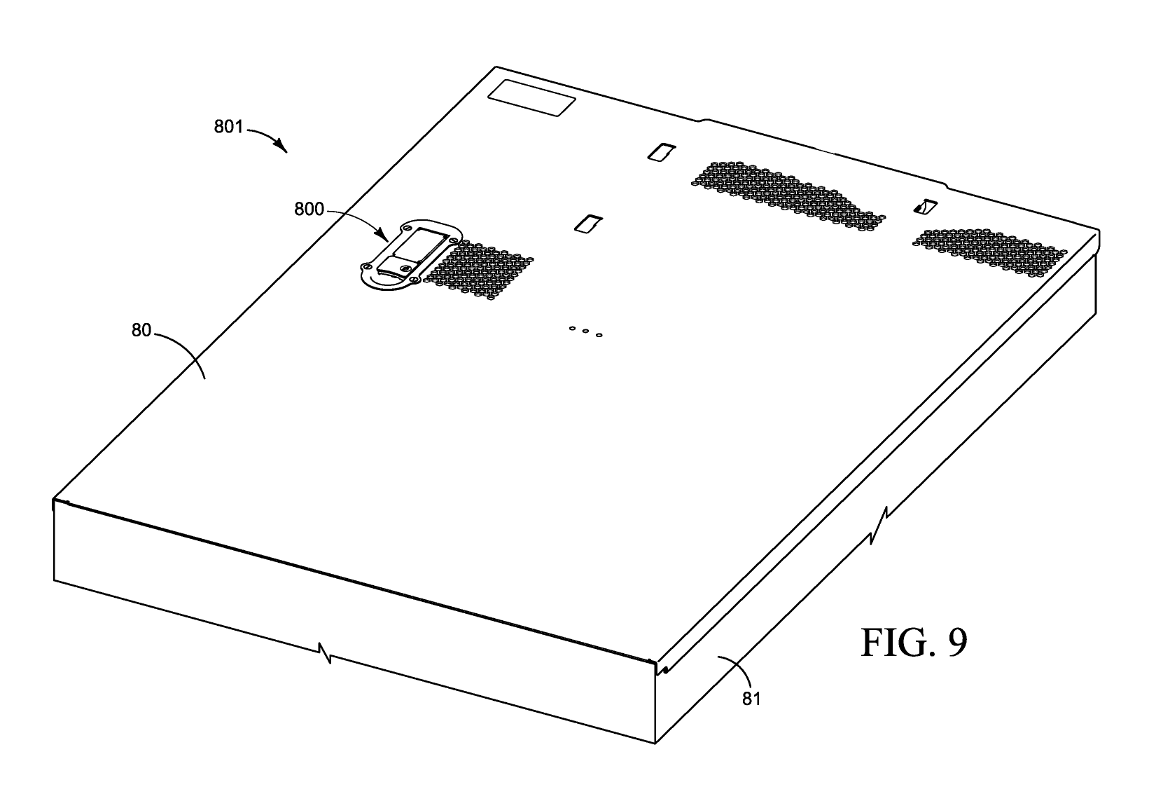

FIG. 8 is a block view illustrating a latch assembly according to an example. FIG. 9 is a schematic view illustrating a server system according to an example. The latch assembly is usable with a hood of a chassis of a server. Referring to FIGS. 8 and 9, in some examples, a server system 801 may include the hood 80, the latch assembly 800, and the chassis 81. The hood 80 may connect to the chassis 81 and cover an interior compartment formed by the chassis 81. The interior compartment, for example, may include electronic components, such as DIMM sockets to receive DIMMs. In some examples, the hood 80 may connect to the chassis 81 and cover the interior compartment formed by the chassis 81 when the hood 80 is in the install hood position. Alternatively, in some examples, the hood 80 may be removed from the chassis 81 to uncover the interior compartment formed by the chassis 81 when the hood 80 is in the uninstall hood position.

Referring to FIGS. 8-9, in some examples, the latch assembly 800 includes a lever 10, a latch member 25, and a cover 14. The lever 10 includes a main portion 11, a cam portion 12, and an end portion 13. The cam portion 12 includes a first cam surface 12a and a second cam surface 12b. The lever 10 rotates between an install hood position and an uninstall hood position. The first cam surface 12a pushes against a first, surface to slide the hood 80 towards the chassis 81 to be placed in the install hood position. The first surface, for example, may include a front wall of a retaining bracket of the chassis 81. In the install hood position, the lever 10 and latch member 25 may be disposed in the cavity 14a of the cover 14. Such an arrangement may provide the latch assembly 800 with a relatively, thin-profile latch assembly. That is, in some examples, a thickness of the latch assembly 800 is in a direction that is normal to a main surface of the hood 80 is in a range of 6.5 mm (latch cover thickness) to 13.4 mm (top of hood to bottom edge of cam portion).

The second cam 12b surface pushes against a second surface to slide the hood 80 away from the chassis 81 to be placed in the uninstall hood position. The second surface, for example, may include a rear wall of the retaining bracket of the chassis 81. In the uninstall hood position, the lever 10 and the latch member 25 may be placed outside of the cavity 14a of the cover 14. The cover 14 couples to the lever 10 and the hood 80.

Referring to FIGS. 8 and 9, in some examples, the latch member 25 is coupled to the end portion 13 of the lever 10. The latch member 25 moves away from the main portion 11 to latch the lever 10 in the install hood position. Further, the latch member 25 moves towards the main portion 11 to unlatch the lever 10 to enable the lever 10 to move to the uninstall hood position. The cover 14 couples to the lever 10 and the hood 80. The cover 14 includes the cavity 14ato receive the lever 10 and the latch member 25. The latch member 25 may also include a hook portion 35a. The hook portion 35a engages the cover 14 in the install hood position in response to when the latch member 25 is placed in the latch position. That is, when engaged, the hook portion 35a, keeps the lever 10 down in the cavity 14a of the cover 14 to prevent the lever 10 from popping up during shock and vibration that may cause the hood 80 to inadvertently come off the chassis 81.

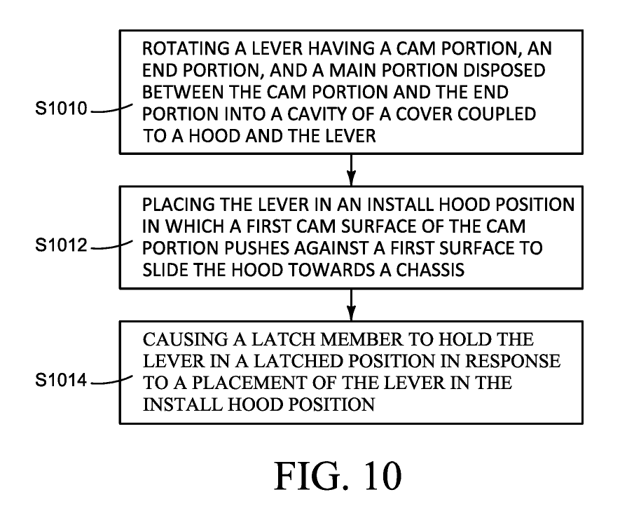

FIG. 10 is a flowchart illustrating a latching method of a latch assembly according to an example. Referring to FIG. 10, in block S1010, a lever having a cam portion, an end portion, and a main portion disposed between the cam portion and the end portion is rotated into a cavity of a cover coupled to a hood and the lever. In block S1012, the lever is placed in an install hood position in which a first cam surface of the cam portion pushes against a first surface to slide the hood towards a chassis. In block S1014, a latch member is caused to hold the lever in a latched position in response to a placement of the lever in the install hood position. For example, the cover may be engaged by a hook portion of the latch member in the install hood position in response to when the latch member is placed in the latch position. In some examples, the latching method may also include locking the latch member in the latch position by moving a lock screw disposed in the latch member to move a lock tab attached thereto of a lock device to a lock position.

It is to be understood that the flowchart of FIG. 10 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG. 10 illustrates a specific order of execution, the order of execution may differ from that which is depicted. For example, the order of execution of two or more blocks may be rearranged relative to the order llustrated. Also, two or more blocks illustrated in succession in FIG. 10 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have”and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform the same function, even if the structure or acts are different, as known in the art. Therefore, the scope of the general inventive concept is limited only by the elements and limitations as used in the claims.

What is claimed is:

1. A latch assembly, comprising:
a lever having a main portion, a cam portion having a first cam surface and a second cam surface, and an end portion;
the lever to rotate between an install hood position in which the first cam surface pushes against a first surface to slide a hood in a first direction and an uninstall hood position in which the second cam surface pushes against a second surface to slide the hood in a second direction; and
a cover to couple to the lever and the hood, the cover having a cavity to receive the lever.

2. The latch assembly of claim 1, wherein the first direction corresponds to a direction towards the chassis and the second direction corresponds to a direction away from the chassis.

3. The latch assembly of claim 1, further comprising;
a latch member coupled to the end portion of the lever, the latch member movable between a latch position to latch the lever in the install hood position and an unlatch position to unlatch the lever.

4. The latch assembly of claim 3, wherein the latch member movable between a latch position to latch the lever in the install hood position and an unlatch position to unlatch the lever further comprises:
the latch member to move away from the main portion of the lever to latch the lever in the install hood position and towards the main portion to unlatch the lever to enable the lever to move to the uninstall hood position.

5. The latch assembly of claimwherein the latch member further comprises:
a hook portion to engage the cover in the install hood position in response to when the latch member is placed in the latch position.

6. The latch assembly of claim 5, wherein the cover further comprises:
a latch recess to receive the hook portion of the latch member in the latch position.

7. The latch assembly of claim 3, further comprising:
a resilient member disposed between the lever and the latch member to provide a force there between.

8. The latch assembly of claim 1, further comprising:
a fastener having a longitudinal axis and to couple the lever to the cover, the lever to rotate about the longitudinal axis.

9. The latch assembly of claim 3, further comprising:
a lock device including a lock screw disposed in the latch member and a lock tab attached to the lock screw, the lock screw to move the lock tab between a lock position and an unlock position.

10. The latch assembly of claim 9, wherein the cover further comprises:
a cover projection to engage the lock tab in the lock position to lock the latch member in the latch position and to disengage the lock tab in the unlock position to unlock the latch member to enable the latch member to move to the unlatch position.

11. A latch assembly, comprising:
a lever having a main portion, a cam portion having a first cam surface and a second cam surface, and an end portion;
the lever to rotate between an install hood position in which the first cam surface pushes against a first surface to slide a hood towards a chassis and an uninstall hood position in which the second cam surface pushes against a second surface to slide the hood away from the chassis;
a latch member coupled to the end portion of the lever, the latch member to move away from the main portion to latch the lever in the install hood position and towards the main portion to unlatch the lever to enable the lever to move to the uninstall hood position; and
a cover to couple to the lever and the hood, the cover having a cavity to receive the lever and the latch member.

12. The latch assembly of claim 11, wherein the latch member further comprises:
a hook portion to engage the cover in the install hood position in response to when the latch member is placed in the latch position.

13. A latching method of a latch assembly, the latching method comprising:
rotating a lever having a cam portion, an end portion, and a main portion disposed between the cam portion and the end portion into a cavity of a cover coupled to a hood and the lever;
placing the lever in an install hood position in which a first cam surface of the cam portion pushes against a first surface to slide the hood towards a chassis, and
causing a latch member to hold the lever in a latched position in response to a placement of the lever in the install hood position.

14. The latching method of claim 13, further comprising:
locking the latch member in the latch position by moving a lock screw disposed in the latch member to move a lock tab attached thereto of a lock device to a lock position.

15. The latching method of claim 13, wherein the cover is engaged by a hook portion of the latch member in the install hood position in response to when the latch member is placed in the latch position.
